(19) United States
(12) Patent Application Publication
(10) Pub. No.: US 2006/0131992 A1
(43) Pub. Date: Jun. 22, 2006

(54) One-port surface acoustic wave resonator and surface acoustic wave filter

(76) Inventors: Takeshi Nakao, Shiga-ken (JP); Tomohisa Komura, Shiga-ken (JP); Michio Kadota, Kyoto-fu (JP)

Correspondence Address: MURATA MANUFACTURING COMPANY, LTD.;C/O KEATING & BENNETT, LLP, 8180 GREENSBORO DRIVE, SUITE 850, MCLEAN, VA, 22102, US

(21) Appl. No.: 10/560,221

(22) PCT Filed: Jun. 10, 2004
(86) PCT No.: PCT/JP04/08116

§ 371 Date: Dec. 12, 2005

(30) Foreign Application Priority Data
Jul. 29, 2003 (JP) 2003-202837

(51) Int. Cl. H03H 9/25

(52) U.S. Cl. 310/313 B

(57) ABSTRACT

A one-port surface acoustic wave resonator includes a rotated Y-cut LiTaO₃ substrate, an interdigital electrode transducer disposed on the LiTaO₃ substrate, and reflectors disposed on both sides of the interdigital electrode transducer in the surface acoustic wave propagation direction of the interdigital electrode transducer. When the electrode finger width of the interdigital electrode transducer is denoted by a and the gap between the electrode fingers is denoted by b, the metallization ratio, a/(a+b), is in the range of about 0.55 to about 0.85 and the interdigital electrode transducer is overlapping-length weighted.

### BACKGROUND OF THE INVENTION

1. Field of the Invention

The present invention relates to one-port surface acoustic wave resonators having reflectors disposed on both sides of an interdigital electrode transducer and relates to surface acoustic wave filters including the one-port surface acoustic wave resonators. More specifically, the present invention relates to one-port surface acoustic wave resonators and surface acoustic wave filters which include a rotated Y-cut LiTaO₃ piezoelectric substrate.

2. Description of the Related Art

A variety of one-port surface acoustic wave resonators including a rotated Y-cut X-propagation LiTaO₃ substrate have been proposed for use as bandpass filters for communication devices. A one-port surface acoustic wave resonator includes an interdigital electrode transducer and reflectors disposed on both sides in the surface acoustic wave propagation direction of the interdigital electrode transducer on a LiTaO₃ substrate. A surface acoustic wave filter using the one-port surface acoustic wave resonator must have small fluctuations of frequency characteristics.

Japanese Unexamined Patent Application Publication No. 7-283682 (Patent Document 1) discloses that good characteristics of one-port surface acoustic wave resonators using the above-mentioned Y-cut X-propagation LiTaO₃ substrate can be obtained by maintaining the ratio (h/λ) of an electrode film thickness (h) to a wavelength (λ) of the surface acoustic wave to the range of 0.06 to 0.10 and by maintaining the metallization ratio of the electrode to 0.6 or less.

Japanese Unexamined Patent Application Publication No. 9-93072 (Patent Document 2) discloses that a yield of ladder-type surface acoustic wave filters having a plurality of one-port surface acoustic wave resonators can be improved by maintaining the metallization ratio of the electrode at 0.6 or more, and preferably, in the range of 0.6 to 0.8.

The ladder-type surface acoustic wave filter having a plurality of one-port surface acoustic wave resonators is commonly used in duplexers as a low-frequency bandpass filter. The ladder-type surface acoustic wave filter of the low-frequency bandpass filter must have steep cut-off characteristics at the blocking band on the higher frequency side of the pass band. Therefore, in order to increase the cut-off steepness, the Q-factor of an antiresonance frequency must be improved in the one-port surface acoustic wave resonators defining a serial arm resonator of a ladder circuit.

Additionally, it is known that the one-port surface acoustic wave resonator is serially connected to a surface acoustic wave filter in order to sufficiently increase the attenuation level at a specific frequency outside of the pass band of the surface acoustic wave filter. Here, a trap is provided at the antiresonance frequency of the one-port surface acoustic wave resonator. With this structure, the Q-factor of the antiresonance frequency of the one-port surface acoustic wave resonator must also be improved.

U.S. Pat. No. 6,556,104 (Patent Document 3) discloses that the Q-factor of the antiresonance frequency can be improved by setting the cut angle of a rotated Y-cut X-propagation LiTaO₃ substrate to 460 or more in the one-port surface acoustic wave resonator using the LiTaO₃ substrate.

T. Matsuda, J. Tsutsumi, S. Inoue, Y. Iwamoto, Y. Satoh, “High-Frequency SAW Duplexer with Low-Loss and Steep Cut-Off Characteristics” IEEE International Ultrasonics Symposium, Oct. 8-11, 2002 (Non-Patent Document 1) discloses that the Q-factor of the antiresonance frequency is increased by controlling the metallization ratio to be less than 0.4 in the one-port surface acoustic wave resonator using a 36° to 42°-rotated Y-cut X-propagation LiTaO₃ substrate.

In a one-port surface acoustic wave resonator using a rotated Y-cut X-propagation LiTaO₃ substrate, the dependency of the acoustic velocity on the metallization ratio is the lowest at a metallization ratio of about 0.75. Specifically, when the metallization ratio is about 0.75, the frequency fluctuation caused by a fluctuation in the precision of electrode formation is the lowest. Therefore, as described in Patent Documents 1 and 2, it is recognized that a metallization ratio of 0.6 or more is preferable for decreasing the frequency fluctuation and for improving the yield.

According to Patent Document 3, in the one-port surface acoustic wave resonator using a rotated Y-cut X-propagation LiTaO₃ substrate, the Q-factor of the antiresonance frequency can be improved by using a LiTaO₃ substrate having a cut angle of 46° or more. However, the Q-factor of the antiresonance frequency sharply deteriorates as the metallization ratio of the electrodes increases, even when the one-port surface acoustic wave resonator including a 46° to 50°-rotated Y-cut LiTaO₃ substrate is used.

According to Non-Patent Document 1, an improved Q-factor of the antiresonance frequency is achieved by decreasing the metallization ratio to be 0.4 or less.

Therefore, in the one-port surface acoustic wave resonator using a Y-cut X-propagation LiTaO₃ substrate, the metallization ratio of the electrode must be increased to 0.5 or more in order to decrease the frequency fluctuation. On the other hand, a metallization ratio must be decreased to 0.4 or less in order to improve the Q-factor of the antiresonance frequency. Thus, it is very difficult to simultaneously improve the Q-factor of the antiresonance frequency and the frequency fluctuation.

### SUMMARY OF THE INVENTION

To overcome the problems described above, preferred embodiments of the present invention provide a one-port surface acoustic wave resonator having a Y-cut X-propagation LiTaO₃ substrate which simultaneously achieves both an improvement of the Q-factor of the antiresonance frequency and a decrease of the frequency fluctuation, and provide a surface acoustic wave filter including the one-port surface acoustic wave resonator.

The one-port surface acoustic wave resonator according to a preferred embodiment of the present invention includes a rotated Y-cut LiTaO₃ substrate, an interdigital electrode transducer provided on the LiTaO₃ substrate, and reflectors disposed at both sides of the interdigital electrode transducer in the surface acoustic wave propagation direction of the interdigital electrode transducer. When the electrode finger width of the interdigital electrode transducer is denoted by a and the gap between the electrode fingers is denoted by b, the metallization ratio, a/(a+b), is in the range of about 0.55 to about 0.85 and the interdigital electrode transducer is overlapping-length weighted.

According to another preferred embodiment of the present invention, the above-mentioned LiTaO₃ substrate preferably has a cut angle of about 36° to about 60°. In the one-port surface acoustic wave resonator including a rotated Y-cut LiTaO₃ substrate, an interdigital electrode transducer provided on the LiTaO₃ substrate, and reflectors disposed at both sides of the interdigital electrode transducer in the surface acoustic wave propagation direction of the interdigital electrode transducer, the metallization ratio, a/(a+b), is in the range of about 0.45 to about 0.85 when the electrode finger width of the interdigital electrode transducer is denoted by a and the gap between the electrode fingers is denoted by b, the interdigital electrode transducer is weighted, and the cut angle of the LiTaO₃ substrate is in the range of about 40° to about 60°. Additionally, in the one-port surface acoustic wave resonator according to a preferred embodiment of the present invention, the amount of the overlapping-length weighting is about 87.5% or less, preferably about 75% or less.

In the one-port surface acoustic wave resonator according to another preferred embodiment of the present invention, the film thickness of the interdigital electrode transducer is set such that the mass is equivalent to that of an aluminum electrode having a film thickness of about 8% to about 14% of the wavelength of the surface acoustic wave, preferably about 8.5% to about 11.5%, and more preferably about 9% to about 11%.

In the one-port surface acoustic wave resonator according to another preferred embodiment of the present invention, the film thickness of the interdigital electrode transducer is set such that the mass is equivalent to that of a copper electrode having a film thickness of about 2.4% to about 4.2% of the wavelength of the surface acoustic wave.

In the one-port surface acoustic wave resonator according to another preferred embodiment of the present invention, the film thickness of the interdigital electrode transducer is set such that the mass is equivalent to that of a gold electrode having a film thickness of about 1.1% to about 2.0% of the wavelength of the surface acoustic wave.

The surface acoustic wave filter according to another preferred embodiment of the present invention includes the one-port surface acoustic wave resonator according to preferred embodiments of the present invention. Examples of the surface acoustic wave filter include, but are not limited to, a ladder-type surface acoustic wave filter, a lattice-type surface acoustic wave filter, and a surface acoustic wave filter having a one-port surface acoustic wave resonator as a trap.

In the one-port surface acoustic wave resonator according to another preferred embodiment of the present invention, an interdigital electrode transducer and a pair of reflectors are disposed on a rotated Y-cut LiTaO₃ substrate and the metallization ratio of the interdigital electrode transducer and the pair of reflectors is in the range of about 0.55 to about 0.85. Consequently, the frequency fluctuation is effectively decreased. Additionally, since the interdigital electrode transducer is overlapping-length weighted, not only is the frequency fluctuation decreased, but the Q-factor of the antiresonance frequency is also effectively increased.

Previously, in a one-port surface acoustic wave resonator, it has been very difficult to simultaneously achieve both a decrease in the frequency fluctuation and an improvement in the Q-factor of the antiresonance frequency. However, according to preferred embodiments of the present invention, the decrease in the frequency fluctuation and the improvement in the Q-factor of the antiresonance frequency are simultaneously achieved by maintaining the metallization ratio of the electrode in the above-mentioned particular range and overlapping-length weighting the interdigital electrode transducer.

Therefore, the cut-off steepness in the filter characteristics from the pass band to the blocking band is increased and the control of the trap using the one-port surface acoustic wave resonator is effectively improved in various surface acoustic wave filters which include the one-port surface acoustic wave resonator according to preferred embodiments of the present invention.

In particular, when the cut angle of the LiTaO₃ substrate is in the range of about 36° to about 60°, the Q-factor of the antiresonance frequency is effectively improved. In the one-port surface acoustic wave resonator including a rotated Y-cut LiTaO₃ substrate, an interdigital electrode transducer provided on the LiTaO₃ substrate, and reflectors disposed at both sides of the interdigital electrode transducer in the surface acoustic wave propagation direction of the interdigital electrode transducer, the frequency fluctuation is effectively decreased by setting the metallization ratio, a/(a+b) to the range of about 0.45 to about 0.85 when the electrode finger width of the interdigital electrode transducer is denoted by a and a gap between the electrode fingers is denoted by b, weighting the interdigital electrode transducer, and also setting the cut angle of the LiTaO₃ substrate to the range of about 40° to about 60°. Additionally, since the interdigital electrode transducer is overlapping-length weighted, not only is the frequency fluctuation decreased, but the Q-factor of the antiresonance frequency is also effectively increased.

The Q-factor of the antiresonance frequency is further effectively improved by setting the amount of the overlapping-length weight to about 87.5% or less, and more preferably to about 75% or less.

When the electrode film thickness is set such that the mass is equivalent to that of an aluminum electrode having a film thickness of about 8% to about 14% of the wavelength of the surface acoustic wave, the Q-factor of the antiresonance is further effectively improved.

Similarly, when the electrode film thickness is set such that the mass is equivalent to that of a copper electrode having a film thickness of about 2.4% to about 4.2% of the wavelength of the surface acoustic wave, the Q-factor of the antiresonance frequency is further effectively improved.

Similarly, when the electrode film thickness is set such that the mass is equivalent to that of a gold electrode having a film thickness of about 1.1% to about 2.0% of the wavelength of the surface acoustic wave, the Q-factor of the antiresonance frequency is further effectively improved.

The surface acoustic wave filter according to preferred embodiments of the present invention includes the one-port surface acoustic wave resonator according to preferred embodiments of the present invention. Therefore, the frequency fluctuation is decreased and the Q-factor of the antiresonance frequency of the one-port surface acoustic wave resonator is also improved. Consequently, cut-off steepness of the filter characteristics from the pass band to the blocking band of the surface acoustic wave filter is increased and the trap characteristics is effectively improved by using the one-port surface acoustic wave resonator as the trap.

These and other features, elements, characteristics and advantages of the present invention will become more apparent from the following detailed description of preferred embodiments of the present invention with reference to the attached drawings.

### BRIEF DESCRIPTION OF THE DRAWINGS

FIG. 1A is a plan view of a one-port surface acoustic wave resonator according to a preferred embodiment of the present invention, and FIG. 1B is an enlarged view of the portion thereof.

FIG. 2 is a graph showing the relationship between the metallization ratio of the electrode and resonance frequency in the one-port surface acoustic wave resonator having a normal-type interdigital electrode transducer in Example 1.

FIG. 3 is a graph showing the relationship between the metallization ratio of the electrode and frequency fluctuation in the surface acoustic wave resonator having a normal-type interdigital electrode transducer in Example 1.

FIG. 4 is a graph showing the relationship between the metallization ratios and the Q-factors of the antiresonance frequency in a comparative example of the one-port surface acoustic wave resonator having a normal-type interdigital electrode transducer and in three examples of the one-port surface acoustic wave resonator which are assigned with overlapping-length weight.

FIG. 5 is a graph schematically showing impedance-frequency characteristics and phase-frequency characteristics when the metallization ratio of the electrode is varied in the one-port surface acoustic wave resonator having a normal-type interdigital electrode transducer.

FIG. 6 is a graph showing the relationship among the cut angle and the metallization ratio of the LiTaO₃ substrate and the Q-factor of the antiresonance frequency, in the one-port surface acoustic wave resonator having a normal-type interdigital electrode transducer.

FIG. 7 is a graph showing the relationship between the metallization ratio of the electrode and the Q-factor of the antiresonance frequency in the one-port surface acoustic wave resonator having a normal-type interdigital electrode transducer.

FIG. 8 is a graph showing the relationship between the metallization ratio of the electrode and the Q-factor of the antiresonance frequency when an aluminum film is further deposited on the busbar of the one-port surface acoustic wave resonator having a normal-type interdigital electrode transducer.

FIG. 9 is a graph schematically showing impedance-frequency characteristics and phase-frequency characteristics in a comparative example of the one-port surface acoustic wave resonator having a normal-type interdigital electrode transducer and in three examples of the one-port surface acoustic wave resonator with overlapping-length weighting at amounts of about 67.5%, about 75%, or about 87.5%.

FIG. 10 is a graph showing the relationship between the aluminum-electrode film thickness and the Q-factor of the antiresonance frequency in an example of the one-port surface acoustic wave resonator having interdigital electrode transducer with overlapping-length weighting.

FIG. 11 is a graph showing the relationship between the cut angle of a LiTaO₃ substrate and the Q-factor of the antiresonance frequency in an example of the one-port surface acoustic wave resonator having interdigital electrode transducer with overlapping-length weighting.

FIG. 12 is a plan view showing an electrode structure of a surface acoustic wave filter having a ladder circuit structure as an example of the surface acoustic wave filter according to a preferred embodiment of the present invention.

FIG. 13 is a plan view showing an electrode structure of a surface acoustic wave filter having a lattice circuit structure as another example of the surface acoustic wave filter according to a preferred embodiment of the present invention.

FIG. 14 is a plan view showing an electrode structure of a surface acoustic wave filter having a trap as another example of the surface acoustic wave filter according to a preferred embodiment of the present invention.

### DETAILED DESCRIPTION OF PREFERRED EMBODIMENTS

Preferred embodiments of the present invention will be described with reference to the drawings.

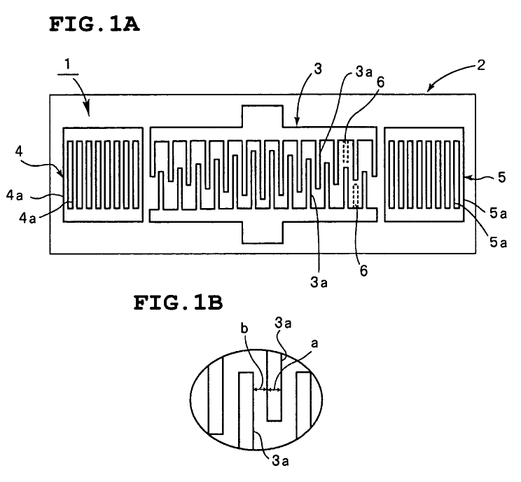

FIG. 1A is a schematic plan view showing a one-port surface acoustic wave resonator according to a preferred embodiment of the present invention, and FIG. 1B is an enlarged view of a portion thereof. The one-port surface acoustic wave resonator 1 includes a rotated Y-cut X-propagation LiTaO₃ substrate 2. The cut angle of the LiTaO₃ substrate is preferably in the range of about 36° to about 60°.

An interdigital electrode transducer 3 is disposed on the LiTaO₃ substrate and reflectors 4 and 5 are disposed on both sides of the interdigital electrode transducer 3 in the surface acoustic wave propagation direction of the interdigital electrode transducer 3. The interdigital electrode transducer 3 and the reflectors 4 and 5 are preferably formed by depositing a metal material, such as aluminum or an aluminum-based alloy, on the LiTaO₃ substrate and then patterning the metal material. Metal materials other than aluminum and the aluminum-based alloy may also be used as the metal material.

The interdigital electrode transducer 3 includes a plurality of interdigitated electrode fingers 3a. Each of the reflectors 4 and 5 preferably includes a plurality of electrode fingers 4a and 5a, respectively.

In the one-port surface acoustic wave resonator 1 according to this preferred embodiment, the interdigital electrode transducer 3 and the reflectors 4 and 5 have a metallization ratio, a/(a+b), of about 0.55 to about 0.85, and the interdigital electrode transducer 3 is overlapping-length weighted as shown in the drawing. As shown in FIG. 1B, the metallization ratio, a/(a+b), is a ratio of an electrode finger width a to the total of the electrode finger width a and a gap b between the electrode fingers, where the electrode finger width of the interdigital electrode transducer 3 is denoted by a and the gap between the electrode fingers is denoted by b.

In this preferred embodiment, as shown in FIG. 1A, the overlapping-length weighting of the interdigital electrode transducer 3 is such that the overlapping-length is the greatest at the center and is reduced toward the outside in the surface acoustic wave propagation direction. FIG. 1A shows an example of the overlapping-length weighting. In FIG. 1A, the overlapping-length at both ends in the surface acoustic wave propagation direction of the interdigital electrode transducer 3 is very small as compared to the overlapping-length at the center, in order to clearly show the overlapping-length weight. In preferred embodiments of the present invention, the overlapping-length weighting is preferably set such that the amount of the weighting is preferably about 87.5% or less, and more preferably, about 75% or less. As a result, the Q-factor of the antiresonance frequency is effectively improved. As shown by broken lines in FIG. 1A, the areas at which the electrodes are removed for weighting may be provided with dummy electrodes 6.

The amount of the overlapping-length weighting means the degree of the overlapping-length weighting. For example, when an envelope curve defined by joining the ends of the electrode fingers providing for the overlapping length is linear, as in the interdigital electrode transducer 3 shown in FIG. 1A, the amount of the overlapping-length weight is represented by (B/A)×100 (%), where A is the maximum overlapping length at the center of the interdigital electrode transducer 3 and B is the minimum overlapping length at both ends in the surface acoustic wave propagation direction of the interdigital electrode transducer 3.

In the interdigital electrode transducer 3, the envelope curve is a line connecting the ends of a plurality of the electrode fingers which are connected to each other at the same electric potential.

As described above, when the overlapping-length weighting is set such that the envelope curve is linear, the amount of the overlapping-length weighting is represented by (B/A)×100 (%). In preferred embodiments of the present invention, the overlapping-length weighting may be assigned such that the envelope curve has a shape other than a line, such as a sine curve. When the overlapping-length weighting is assigned such that the envelope curve has a shape other than a line, the dimensions of the area at which the overlapping-length weighting is assigned is determined on the basis of the dimensions of an area at which the overlapping-length weighting would be assigned if the envelope curve were linear. Specifically, when the dimensions of the area at which the weighting is assigned such that the envelope curve has a shape other than a line is Y, the dimensions of the area at which the weighting would be assigned if the envelope curve has a line is Y and (B/A)×100 (%) is Z; the amount of the overlapping-length weighting in the case that the envelope curve has the shape other than a line is assigned as Z.

In the one-port surface acoustic wave resonator 1, the interdigital electrode transducer 3 and the reflectors 4 and 5 are formed on the LiTaO₃ substrate such that the metallization ratio is in the range of about 0.45 to about 0.85. Therefore, as will be apparent from the examples described below, the antiresonance frequency fluctuation caused by a fluctuation in the electrode precision is effectively decreased.

Additionally, the Q-factor of the antiresonance frequency is significantly improved because the interdigital electrode transducer 3 is overlapping-length weighted. This will be described with reference to the following concrete examples.

### EXAMPLE 1

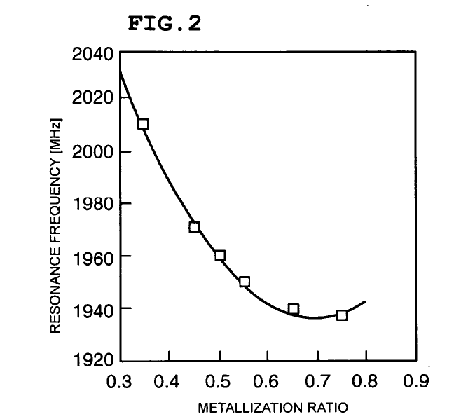

Rotated Y-cut X-propagation LiTaO₃ substrates were prepared. A normal-type interdigital electrode transducer and a pair of reflectors were formed of aluminum on each of the LiTaO₃ substrates at various metallization ratios. Then, resonance frequencies were determined. FIG. 2 shows the results. The wavelength of the interdigital electrode transducer 3 was adjusted to about 2 μm. The target resonance frequency was a resonance frequency of about 2 GHz, and the electrode film thickness was about 10% of the wavelength. With reference to FIG. 2, it was confirmed that the resonance frequency varied as the metallization ratio of the interdigital electrode transducer and the reflectors changed. It was also observed that the resonance frequency was the lowest at a metallization ratio of about 0.7.

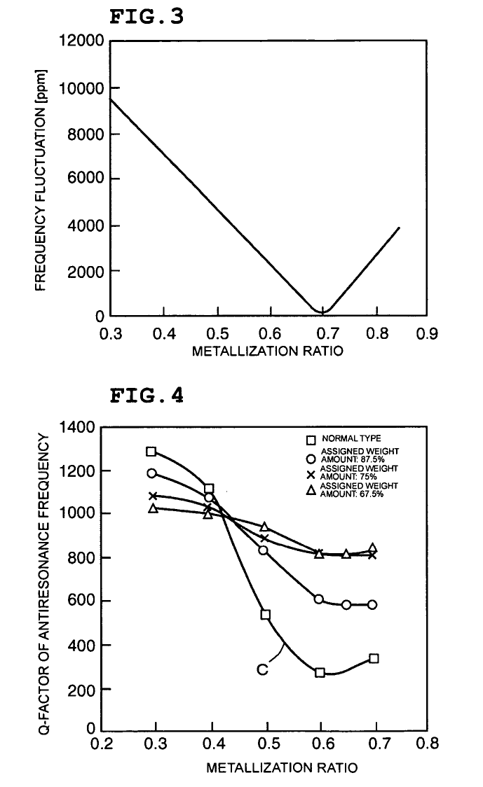

One-port surface acoustic wave resonators having various metallization ratios were prepared by the same manner as described above. Resonance frequency fluctuation was determined when the size fluctuation in the width direction of the electrode fingers was about ±0.02 μm. FIG. 3 shows the results.

The frequency fluctuation on the vertical axis in FIG. 3 is a ratio (ppm) of a difference between an actual value of the resonance frequency of the prepared surface acoustic wave resonator and a target resonance frequency of 2 GHZ to the target resonance frequency of 2 GHz.

With reference to FIG. 3, it was observed that the frequency fluctuation was the lowest at a metallization ratio of about 0.7.

A frequency fluctuation of about 4,000 ppm or less is preferable where a smaller frequency tolerance is required. With reference to FIG. 3, it was observed that the requirement could be satisfied by maintaining the metallization ratio in the range of about 0.55 to about 0.85.

The inventors confirmed that the preferable range of the metallization ratio shown in FIG. 3 is not dependent upon the electrode film thickness, by comparing the results of an experiment performed using aluminum electrodes having various film thicknesses.

### EXAMPLE 2

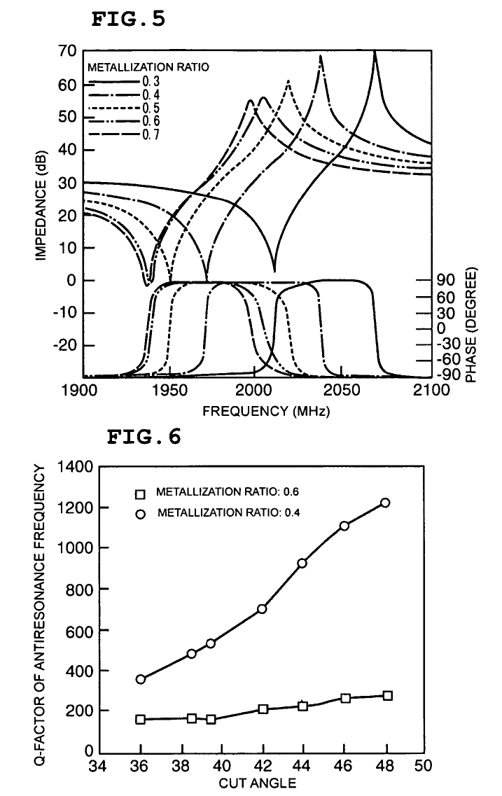

A one-port surface acoustic wave resonator included a normal-type interdigital electrode transducer and a pair of reflectors which were prepared as described in Example 1. In this example, the Y-cut X-propagation LiTaO₃ substrate had a cut angle of about 46°, the wavelength was about 2 μm, the film thickness of the interdigital electrode transducer and the reflectors was about 10% of the wavelength, the number of electrode finger pairs of the interdigital electrode transducer was 125, the overlapping-length of the electrode fingers was about 32 μm, and the target resonance frequency was about 2 GHz. The metallization ratios of the one-port surface acoustic wave resonators were varied, and Q-factors of the antiresonance frequency were determined. The results are shown in FIG. 4 by a solid line C. FIG. 5 shows impedance-frequency characteristics and phase-frequency characteristics.

As shown by the solid line C in FIG. 4 and the wave patterns in FIG. 5, in the area where the metallization ratio is greater than about 0.45, the Q-factor of the antiresonance frequency is significantly decreased to about 800 or less. On the other hand, the Q-factor is favorably about 800 or greater when the metallization ratio is about 0.45 or less. This tendency is consistent with the content described in the above-mentioned Non-Patent Document 1.

Therefore, in view of the results of Example 1 and Example 2, it is observed that the frequency fluctuation exceeds about 7,000 ppm in the conventional one-port surface acoustic wave resonator, even if the metallization ratio is maintained to about 0.4 in order to obtain a good Q-factor of the antiresonance frequency. This frequency fluctuation is about 14 MHz if the resonance frequency is about 2 GHz. Therefore, this frequency fluctuation is a crucial defect in a device, such as a mobile phone, having a narrow frequency difference of about 20 MHz between a transmission band and a reception band. Additionally, it is also highly desirable in other applications to decrease this large frequency fluctuation.

However, as confirmed in Examples 1 and 2, it has been very difficult to simultaneously achieve both a decrease in the frequency fluctuation and a good Q-factor of the antiresonance frequency.

### EXAMPLE 3

As described in the above-mentioned Patent Document 3, the Q-factor of the antiresonance frequency can be improved by maintaining the cut angle of the LiTaO₃ substrate in the range of about 46° to about 54°. Two types of one-port surface acoustic wave resonators having a metallization ratio of about 0.4 and about 0.6 were prepared using Y-cut LiTaO₃ substrates having various cut angles, as in Example 2. FIG. 6 shows the relationship between the cut angles of the LiTaO₃ substrates in the resulting surface acoustic wave resonators and the Q-factors of the antiresonance frequency.

As shown in FIG. 6, when the metallization ratio was about 0.4, the Q-factor of the antiresonance frequency was greatly improved by increasing the cut angle. On the other hand, when the metallization ratio was about 0.6, the Q-factor of the antiresonance frequency was not substantially improved by increasing the cut angle.

As shown in Example 3, the Q-factor of the antiresonance frequency cannot be improved because of the cut angle characteristics even if the metallization ratio is set to about 0.6 for improving the frequency fluctuation.

### EXAMPLE 4

In the above-mentioned Non-Patent Document 1, the Q-factor of the antiresonance frequency is improved by decreasing the metallization ratio of electrodes. The cause of this improvement is thought to be due to the waveguiding effect. Specifically, the acoustic velocity at the surface acoustic wave propagation portion of the interdigital electrode transducer is sufficiently faster than that at a busbar when the metallization ratio is small. Consequently, the locked-in effect of the interdigital electrode transducer as the waveguide is improved. Thus, leakage of the surface acoustic wave from the busbar to the outside of the resonator is decreased so as to improve the Q-factor of the antiresonance frequency.

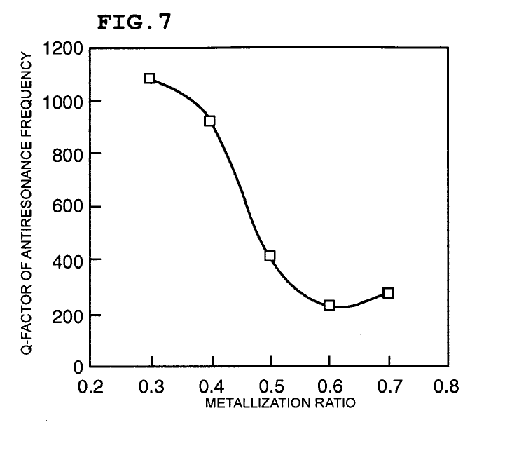

Therefore, the inventors believe that the Q-factor may be improved by decreasing the acoustic velocity at the busbar instead of by increasing the acoustic velocity in the interdigital electrode transducer. Therefore, an aluminum film having a thickness of about 1 μm was deposited on only the busbar of each of the surface acoustic wave resonators having electrodes of various metallization ratios as in Example 2. FIG. 7 shows the relationship between the Q-factor of the antiresonance frequency and the metallization ratio of the surface acoustic wave resonator before the deposition of the second layer of the aluminum film having a thickness of about 1 μm on the busbar. The results shown in FIG. 7 are the same as the solid line C in the above-mentioned FIG. 4.

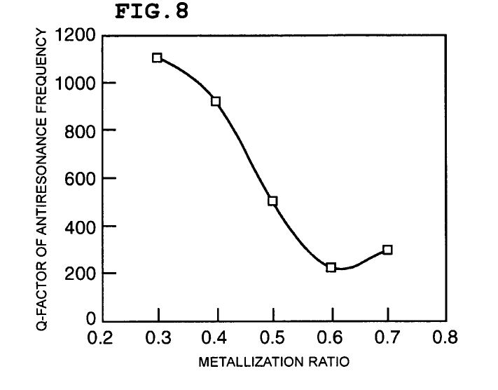

FIG. 8 shows the relationship between the Q-factor of the antiresonance frequency and the metallization ratio of the surface acoustic wave resonator after the deposition of the second layer of the aluminum film on the busbar. As shown in FIG. 7 and FIG. 8, the Q-factor of the antiresonance frequency is not substantially improved, even when the acoustic velocity of the busbar is reduced. Specifically, the improvement of the Q-factor of the antiresonance frequency by controlling the relationship between the acoustic velocity at the busbar and the acoustic velocity at the interdigital electrode transducer is difficult.

### EXAMPLE 5

From the results of Examples 3 and 4, the inventors do not believe that the main causes of the deterioration in the Q-factor of the antiresonance frequency when the metallization ratio is large are leakage components of the surface acoustic wave to the inside of the substrate and leakage components of the surface acoustic wave to the outside from the busbar. Furthermore, it was confirmed that the Q-factor of the antiresonance frequency was not improved by increasing the number of the reflector. Specifically, it is not thought that the cause is the leakage of the surface acoustic wave due to a shortage of reflectors.

The inventors have extensively studied and determined that the Q-factor of the antiresonance frequency can be improved by weighting, in particular, by overlapping-length weighting the interdigital electrode transducer 3.

In Example 5, one-port surface acoustic wave resonators were prepared in the same manner as in Example 2 except that the interdigital electrode transducers were overlapping-length weighted. In this case, various types of the one-port surface acoustic wave resonators were prepared by varying the above-mentioned amounts of overlapping-length weighting. The metallization ratio of the electrodes was about 0.6.

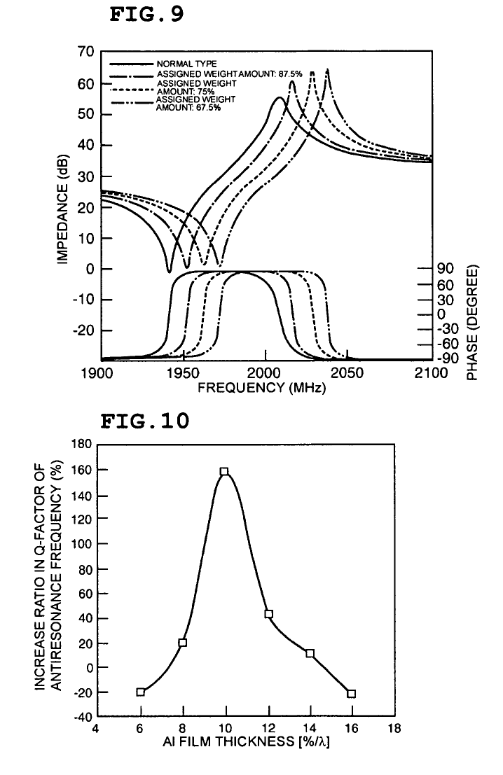

FIG. 9 shows the results. FIG. 9 shows graphs of the impedance-frequency characteristics and phase-frequency characteristics of various types of one-port surface acoustic wave resonators. FIG. 9 shows one-port surface acoustic wave resonator characteristics of a comparative example in which a normal-type interdigital electrode transducer is used and of three examples in which the amount of weighting is about 87.5%, about 75%, and about 67.5%. In FIG. 9, the frequency characteristics of the various types of surface acoustic wave resonators are slightly shifted to facilitate understanding thereof. Therefore, each characteristic is separately illustrated.

The Q-factors of the antiresonance frequency were determined by changing the metallization ratio of electrodes in the plurality of one-port surface acoustic wave resonators having overlapping-length weighting. The results are shown in the above-mentioned FIG. 4 by solid lines ◯, ×, and Δ. In FIG. 4, ◯, ×, and Δ show the results when the amounts of overlapping-length weighting were about 87.5%, about 75%, and about 67.5%, respectively.

As shown in FIG. 4 and FIG. 9, the Q-factor of the antiresonance frequency is greatly improved by overlapping-length weighting the interdigital electrode transducer. Additionally, as shown in FIG. 9, the resonance characteristics were not substantially changed when interdigital electrode transducer included the above-mentioned overlapping-length weighting. Therefore, the decrease in the frequency fluctuation and the improvement in Q-factor of the antiresonance are simultaneously achieved by overlapping-length weighting the interdigital electrode transducer, even when the metallization ratio was large, such as about 0.45 or more. In particular, the Q-factor of the antiresonance frequency and the frequency fluctuation are effectively improved by overlapping-length weighting the interdigital electrode transducer, preferably with overlapping-length weighting of about 87.5% or less, and more preferably, with overlapping-length weighting of about 75% or less, when the metallization ratio is in the range of about 0.55 to about 0.85.

### EXAMPLE 6

As shown in Example 5, even when the metallization ratio is large, such as in the range of about 0.45 to about 0.85, the Q-factor of the antiresonance frequency is effectively improved by overlapping-length weighting the interdigital electrode transducer. Next, influences of the electrode film thickness on this effect were investigated. In the one-port surface acoustic wave resonators using a 48°-rotated LiTaO₃ substrate and including overlapping-length weighting of about 75%, improvement ratios (%) of the Q-factor of the antiresonance frequency were determined by varying the electrode film thickness. The metallization ratio was about 0.5. FIG. 10 shows the results.

As shown in FIG. 10, the Q-factor of the antiresonance frequency is improved by the overlapping-length weighting when the aluminum-electrode film thickness is in the range of about 8% to about 14% of a wavelength of the surface acoustic wave. In particular, the Q-factor is improved by about 50% or more when the aluminum-electrode film thickness is in the range of about 8.5% to about 11.5% and is improved by about 100% or more when the electrode film thickness is in the range of about 9% to about 11%.

Therefore, in the present invention, the range of the electrode film thickness is preferably about 8% to about 14% of the wavelength, more preferably about 8.5% to about 11.5%, and most preferably about 9% to about 11%, when the electrode is made of aluminum.

Furthermore, when the electrode is made of a metal material other than aluminum, such as copper or gold, or when the electrode is formed by laminating a plurality of metal materials, similar results are obtained as long as the electrode has a thickness that is equivalent to the mass and the film thickness of the above-mentioned aluminum-electrode film thickness.

Specifically, an aluminum-electrode film thickness of about 8% to about 14% of the wavelength is equivalent to a copper-electrode film thickness of about 2.4% to about 4.2% of the wavelength and is equivalent to a gold-electrode film thickness of about 1.1% to about 2.0% of the wavelength. Similarly, an aluminum-electrode film thickness of about 8.5% to about 11.5% or about 9.0% to about 11.0% of the wavelength is equivalent to a copper-electrode film thickness of about 2.6% to about 3.5% or about 2.7% to about 3.3%, respectively, and is equivalent to a gold-electrode film thickness of about 1.2% to about 1.6% or about 1.3% to about 1.5%, respectively.

### EXAMPLE 7

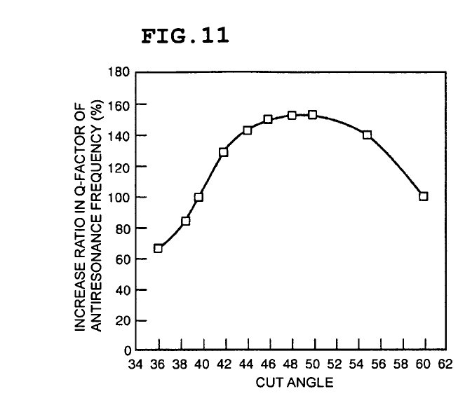

In Example 7, increase ratios of the Q-factor of the antiresonance frequency were determined by varying the cut angle of the LiTaO₃ substrate. The interdigital electrode transducers were the same as those in Example 6, and the aluminum-electrode film thickness was about 10% of the wavelength of the surface acoustic wave. FIG. 11 shows the results.

As shown in FIG. 11, according to preferred embodiments of the present invention, the Q-factor of the antiresonance frequency is improved in all of the cut angles of the LiTaO₃ substrate. In particular, when the cut angle is about 40° to about 60°, improvement effects on the Q-factor caused by using the interdigital electrode transducer including overlapping-length weighting was about 100% or more as compared to the case of a normal-type interdigital electrode transducer. Furthermore, when the cut angle is about 44° to about 54°, the cut angle also improves the Q-factor of the antiresonance frequency. As a result, the Q-factor of the antiresonance frequency is further effectively improved with the Q-factor-improvement effect by the overlapping-length weighting the interdigital electrode transducer. Therefore, a metallization ratio of about 0.45 to about 0.85 and a cut angle of about 40° to about 60° are preferable.

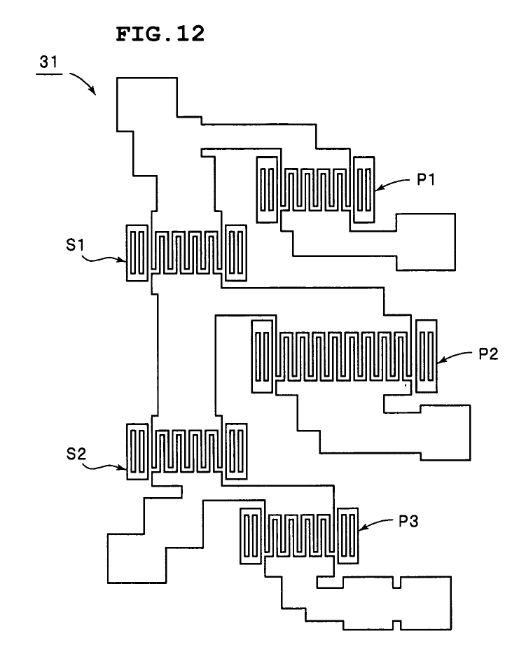

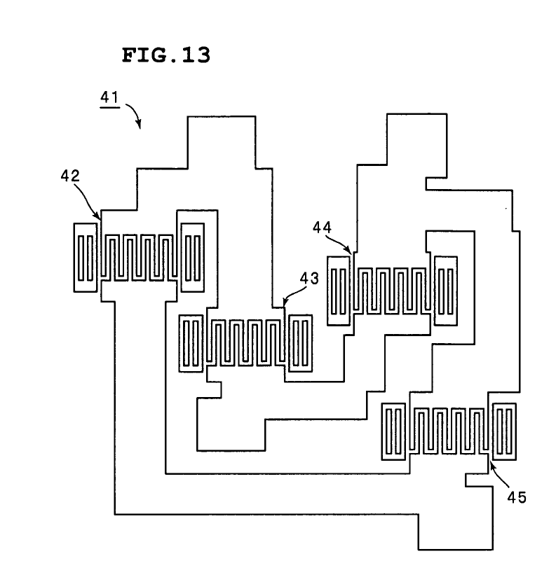

In the one-port surface acoustic wave resonator according to preferred embodiments of the present invention, the frequency fluctuation and the Q-factor of the antiresonance frequency are simultaneously improved by maintaining the metallization ratio in the range of about 0.45 to about 0.85, and preferably in the range of about 0.55 to about 0.85, and by using an interdigital electrode transducer with overlapping-length weighting. Therefore, the cut-off steepness of the filter characteristics is effectively improved with a providing a surface acoustic wave filter including the one-port surface acoustic wave resonator according to preferred embodiments of the present invention, and the attenuation level of the blocking band of a surface acoustic wave filter is effectively improved by using the one-port surface acoustic wave resonator as a trap. Examples of the one-port surface acoustic wave resonator according to preferred embodiments of the present invention and the surface acoustic wave filter using the one-port surface acoustic wave resonator include, but are not limited to, the surface acoustic wave filters shown in FIGS. 12 to 14.

The surface acoustic wave filter shown in FIG. 12 is a ladder-type surface acoustic wave filter 31 and includes a plurality of serial arm resonators S1 and S2 and parallel arm resonators P1 to P3. The one-port surface acoustic wave resonator according to preferred embodiments of the present invention may be used as such a serial arm resonator or parallel arm resonator. In particular, the Q-factor of the antiresonance frequency in the serial arm resonators S1 and S2 can be improved by using the one-port surface acoustic wave resonator according to preferred embodiments of the present invention as the serial arm resonators S1 and S2. With this, the cut-off steepness in the filter characteristics is increased at the higher frequency side of the pass band of the ladder-type surface acoustic wave filter 31.

The surface acoustic wave filter shown in FIG. 13 is a surface acoustic wave filter 41 having a lattice circuit arrangement, and a plurality of one-port surface acoustic wave resonators 42 to 45 are connected to each other so as to have grid connection. The one-port surface acoustic wave resonator according to preferred embodiments of the present invention is suitable for use as the one-port surface acoustic wave resonators 42 to 45.

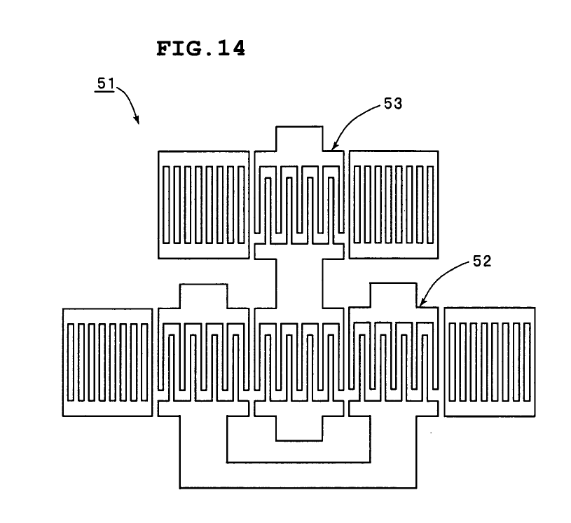

FIG. 14 shows a surface acoustic wave filter 51 using a one-port surface acoustic wave resonator defining a trap. In the surface acustic wave filter 51, the one-port surface acoustic wave resonator 53 is connected with a surface acoustic wave filter portion 52 to define the trap. Favorable trap characteristics are obtained by using the antiresonance frequency of the one-port surface acoustic wave resonator according to preferred embodiments of the present invention used as the one-port surface acoustic wave resonator 53.

While the surface acoustic wave device of the present invention has been described with respect to preferred embodiments thereof, it will be apparent to those skilled in the art that the disclosed invention may be modified in numerous ways and may assume many embodiments other than those specifically set out and described above. Accordingly, it is intended by the appended claims to cover all modifications of the invention which fall within the true spirit and scope of the present invention.

1-9. (canceled)

10. A one-port surface acoustic wave resonator comprising:
a rotated Y-cut LiTaO₃ substrate;
an interdigital electrode transducer disposed on the LiTaO₃ substrate and including electrode fingers; and
reflectors disposed on both sides of the interdigital electrode transducer in a surface acoustic wave propagation direction of the interdigital electrode transducer; wherein
when an electrode finger width of the electrode fingers of the interdigital electrode transducer is denoted by a and a gap between the electrode fingers is denoted by b, a metallization ratio, a/(a+b), is in the range of about 0.55 to about 0.85; and
the interdigital electrode transducer is overlapping-length weighted.

11. The one-port surface acoustic wave resonator according to claim 10, wherein a cut angle of the LiTaO₃ substrate is in the range of about 36° to about 60°.

12. The one-port surface acoustic wave resonator according to claim 10, wherein the amount of the overlapping-length weighting is about 87.5% or less.

13. The one-port surface acoustic wave resonator according to claim 10, wherein the amount of the overlapping-length weighting is about 75% or less.

14. The one-port surface acoustic wave resonator according to claim 10, wherein a film thickness of the interdigital electrode transducer is set such that a mass is equivalent to that of an aluminum electrode having a film thickness of about 8% to about 14% of the wavelength of the surface acoustic wave.

15. The one-port surface acoustic wave resonator according to claim 10, wherein a film thickness of the interdigital electrode transducer is set such that a mass is equivalent to that of an aluminum electrode having a film thickness of about 9% to about 11% of the wavelength of the surface acoustic wave.

16. The one-port surface acoustic wave resonator according to claim 10, wherein a film thickness of the interdigital electrode transducer is set such that the mass is equivalent to that of a copper electrode having a film thickness of about 2.4% to about 4.2% of the wavelength of the surface acoustic wave.

17. The one-port surface acoustic wave resonator according to claim 10, wherein a film thickness of the interdigital electrode transducer is set such that the mass is equivalent to that of a gold electrode having a film thickness of about 1.1% to about 2.0% of the wavelength of the surface acoustic wave.

18. A surface acoustic wave filter including the one-port surface acoustic wave resonator according to claim 10.

19. The surface acoustic wave filter according to claim 18, wherein the surface acoustic wave filter is one of a ladder-type surface acoustic wave filter, a lattice-type surface acoustic wave filter, and a surface acoustic wave filter provided with the one-port surface acoustic wave resonator as a trap.

20. A one-port surface acoustic wave resonator comprising:
a rotated Y-cut LiTaO₃ substrate;
an interdigital electrode transducer disposed on the LiTaO₃ substrate and including electrode fingers; and
reflectors disposed on both sides of the interdigital electrode transducer in the surface acoustic wave propagation direction of the interdigital electrode transducer; wherein
a metallization ratio, a/(a+b), is in the range of about 0.45 to about 0.85, where an electrode finger width of the electrode fingers of the interdigital electrode transducer is denoted by a and a gap between the electrode fingers is denoted by b;
the interdigital electrode transducer is overlapping-length weighted; and
a cut angle of the LiTaO₃ substrate is in the range of about 40° to about 60°.

21. The one-port surface acoustic wave resonator according to claim 20, wherein the amount of the overlapping-length weighting is about 87.5% or less.

22. The one-port surface acoustic wave resonator according to claim 20, wherein the amount of the overlapping-length weighting is about 75% or less.

23. The one-port surface acoustic wave resonator according to claim 20, wherein a film thickness of the interdigital electrode transducer is set such that the mass is equivalent to that of an aluminum electrode having a film thickness of about 8% to about 14% of the wavelength of the surface acoustic wave.

24. The one-port surface acoustic wave resonator according to claim 20, wherein a film thickness of the interdigital electrode transducer is set such that a mass is equivalent to that of an aluminum electrode having a film thickness of about 9% to about 11% of the wavelength of the surface acoustic wave.

25. The one-port surface acoustic wave resonator according to claim 20, wherein a film thickness of the interdigital electrode transducer is set such that the mass is equivalent to that of a copper electrode having a film thickness of about 2.4% to about 4.2% of the wavelength of the surface acoustic wave.

26. The one-port surface acoustic wave resonator according to claim 20, wherein a film thickness of the interdigital electrode transducer is set such that the mass is equivalent to that of a gold electrode having a film thickness of about 1.1% to about 2.0% of the wavelength of the surface acoustic wave.

27. A surface acoustic wave filter including the one-port surface acoustic wave resonator according to claim 20.

28. The surface acoustic wave filter according to claim 27, wherein the surface acoustic wave filter is one of a ladder-type surface acoustic wave filter, a lattice-type surface acoustic wave filter, and a surface acoustic wave filter provided with the one-port surface acoustic wave resonator as a trap.
